(19) United States
(12) Patent Application Publication
(10) Pub. No.: US 2026/0060031 A1
(43) Pub. Date: Feb. 26, 2026

(54) SEMICONDUCTOR SUBSTRATE PLACEMENT ROBOT

(71) Applicant: Applied Materials, Inc., Santa Clara, CA (US)

(72) Inventors: Ka Shun WONG, Santa Clara, CA (US); Martin Jay SEAMONS, San Jose, CA (US); Ganesh BALASUBRAMANIAN, Fremont, CA (US)

(21) Appl. No.: 18/912,717

(22) Filed: Oct. 11, 2024

Related U.S. Application Data
(60) Provisional application No. 63/685,963, filed on Aug. 22, 2024.

(51) Int. Cl. H01L 21/677; G05B 19/4099; G06T 7/73; H01L 21/68

(52) U.S. Cl. CPC H01L 21/67751; G05B 19/4099; G06T 7/73; H01L 21/681; G05B 2219/45031; G06T 2207/30148

(57) ABSTRACT

The present disclosure describes a semiconductor substrate processing system that places a semiconductor substrate in a process chamber using images captured by cameras positioned on the substrate. A controller for moving a semiconductor substrate includes a memory and a processor. The processor receives a first image from a first camera positioned on the semiconductor substrate and a second image from a second camera positioned on the semiconductor substrate. The first camera is different from the second camera. The processor also detects a first lift pin hole in the first image and a second lift pin hole in the second image, determines, based on a position of the first lift pin hole in the first image and a position of the second lift pin hole in the second image, an offset for the semiconductor substrate, and moves a robot holding the semiconductor substrate based on the offset.

### CROSS-REFERENCE TO RELATED APPLICATIONS

This application claims priority to U.S. Provisional Patent Application Ser. No. 63/685,963, filed on Aug. 22, 2024, which is herein incorporated by reference in its entirety.

### BACKGROUND

### Field

The present disclosure generally relates to a semiconductor substrate placement robot. Specifically, the present disclosure describes a robot that positions a semiconductor substrate in a process chamber.

### Description of the Related Art

Semiconductor substrate processing systems perform various processes on semiconductor substrates (e.g., cleaning, etching, deposition, etc.) to form them into semiconductor devices (e.g., integrated circuits). The substrates are transported from a substrate load lock chamber onto susceptors (e.g., support platforms) in the process chambers using a transport robot.

A susceptor generally includes a pocket in which the substrate is placed. The pocket on the susceptor generally has a diameter only slightly larger than the diameter of the substrate. As a result, there may be a small clearance between the edge of the substrate and the edge of the susceptor pocket. If the substrate is offset from the center of the susceptor pocket, the substrate may contact the sidewalls of the pocket or be placed outside the pocket, which may cause non-uniformity in process results, temperature gradients in the chamber, and even arcing that damages the substrate and/or the chamber.

### SUMMARY

The present disclosure describes a semiconductor substrate processing system that places a semiconductor substrate in a process chamber using images captured by cameras positioned on the substrate. According to an embodiment, a controller for moving a semiconductor substrate includes one or more memories and one or more processors communicatively coupled to the one or more memories. A combination of the one or more processors receives a first image from a first camera positioned on the semiconductor substrate and a second image from a second camera positioned on the semiconductor substrate. The first camera is different from the second camera. The combination of the one or more processors also detects a first lift pin hole in the first image and a second lift pin hole in the second image, determines, based on a position of the first lift pin hole in the first image and a position of the second lift pin hole in the second image, an offset for the semiconductor substrate, and moves a robot holding the semiconductor substrate based on the offset.

According to another embodiment, a method for moving a semiconductor substrate includes receiving a first image from a first camera positioned on a semiconductor substrate and a second image from a second camera positioned on the semiconductor substrate. The first camera is different from the second camera. The method also includes detecting a first lift pin hole in the first image and a second lift pin hole in the second image, determining, based on a position of the first lift pin hole in the first image and a position of the second lift pin hole in the second image, an offset for the semiconductor substrate, and moving a robot holding the semiconductor substrate based on the offset.

According to another embodiment, a non-transitory computer readable medium stores instructions for moving a semiconductor substrate. When the instructions are executed by a combination of one or more processors, the instructions cause the combination of the one or more processors to receive a first image from a first camera positioned on the semiconductor substrate and a second image from a second camera positioned on the semiconductor substrate. The first camera is different from the second camera. The instructions also cause the combination of the one or more processors to detect a first lift pin hole in the first image and a second lift pin hole in the second image, determine, based on a position of the first lift pin hole in the first image and a position of the second lift pin hole in the second image, an offset for the semiconductor substrate, and move a robot holding the semiconductor substrate based on the offset.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a schematic view of an example semiconductor substrate processing system, according to certain embodiments of the present disclosure.

FIG. 2 illustrates a schematic side cross-sectional views of example process chambers for the semiconductor substrate processing system of FIG. 1, according to certain embodiments of the present disclosure.

FIGS. 3A and 3B illustrate an example semiconductor substrate in the semiconductor substrate processing system of FIG. 1, according to certain embodiments of the present disclosure.

FIG. 4 illustrates an example operation performed by the semiconductor substrate processing system of FIG. 1, according to certain embodiments of the present disclosure.

FIG. 5 illustrates example images in the semiconductor substrate processing system of FIG. 1, according to certain embodiments of the present disclosure.

FIG. 6 is a flowchart of an example method performed by the semiconductor substrate processing system of FIG. 1, according to certain embodiments of the present disclosure.

FIG. 7 is a schematic cross sectional view of an example process chamber for the semiconductor substrate processing system of FIG. 1, according to certain embodiments of the present disclosure

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure describes a semiconductor substrate processing system that positions a semiconductor substrate in a process chamber based on images captured by cameras on the surface of the semiconductor substrate. Generally, multiple cameras are positioned on a bottom surface of the substrate, and these cameras may be positioned to align with lift pin holes in the process chamber. When a robot is about to place the substrate onto the lift pin holes, the cameras may capture images of the lift pin holes. The system may determine, from the positions of the lift pin holes in the images, whether the substrate is offset from the lift pin holes. The system may then move the robot to move the substrate into better alignment with the lift pin holes. In some instances, the system saves the position of the robot so that the system may move the robot into that position for subsequent substrates. In this manner, the system reuses the results of the calibration for subsequent substrates.

In certain embodiments, the semiconductor substrate processing system provides several technical advantages. For example, the system may improve the alignment of the semiconductor substrate with the lift pin holes and the susceptor. Because the lift pin holes are fixed on the susceptor, aligning the semiconductor substrate with the lift pin holes may provide a more consistent alignment between the semiconductor substrate and the susceptor. As a result, the process results on the substrate may be more uniform. Additionally, there may be fewer temperature gradients in the process chamber and less or no arcing in the process chamber.

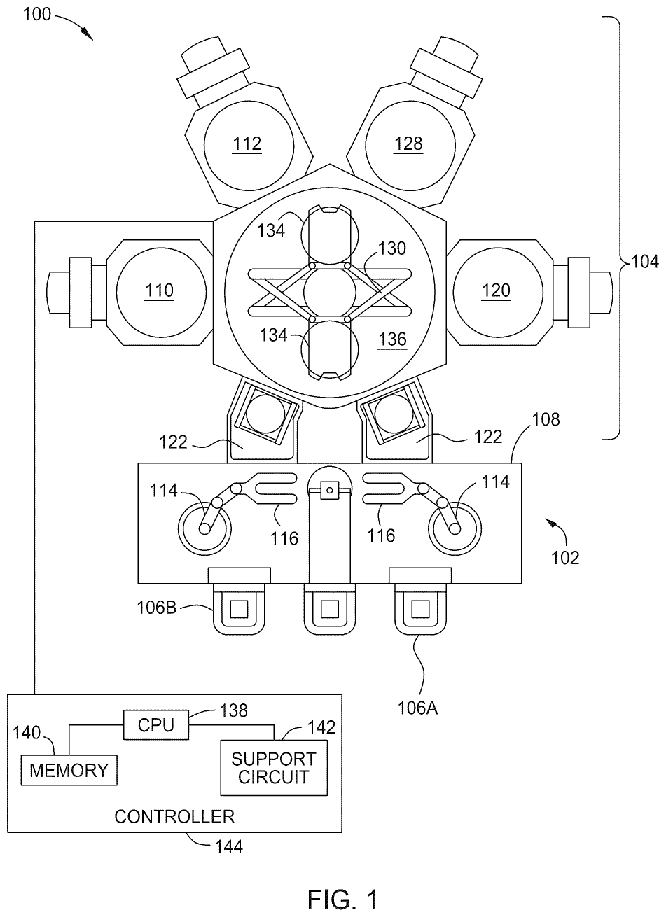

FIG. 1 illustrates a schematic view of an example semiconductor substrate processing system 100, according to certain embodiments of the present disclosure. As seen in FIG. 1, the processing system 100 includes a factory interface 102, a vacuum-tight processing platform 104, one or more substrate load lock chambers 122, and a controller 144. The platform 104 includes multiple processing chambers 110, 112, 120, and 128, and the substrate load lock chambers 122 are coupled to a vacuum substrate transfer chamber 136. The factory interface 102 is coupled to the transfer chamber 136 through two substrate load lock chambers 122.

The factory interface 102 may include a docking station 108 and one or more factory interface robots 114 to facilitate the transfer of substrates. The docking station 108 may accepts one or more front opening unified pods (FOUPs) 106. Two FOUPS 106A and 106B are shown in the example of FIG. 1. A factory interface robot 114 includes a blade 116 disposed on one end of the robot 114. The robot 114 may use the blade 116 to transfer one or more substrates from the FOUPS 106A and 106B through the substrate load lock chambers 122 to the processing platform 104 for processing. In certain embodiments, substrates being transferred may be stored in the substrate load lock chambers 122.

Each of the substrate load lock chambers 122 has a first port interfacing with the factory interface 102 and a second port interfacing with the transfer chamber 136. The substrate load lock chambers 122 are coupled to a pressure control system (not shown) which pumps down and vents the substrate load lock chambers 122 to facilitate passing the substrates between the vacuum environment of the transfer chamber 136 and a substantially ambient (e.g., atmospheric) environment of the factory interface 102.

A transfer robot 130 is positioned within the transfer chamber 136. The transfer robot 130 includes blades 134 that the transfer robot 130 uses to transfer the substrates between the substrate load lock chambers 122 and the processing chambers 110, 112, 120, and 128.

The controller 144 controls the operations of the system 100 to perform any of the operations or actions described herein. The controller 144 may collect data and feedback from the process chambers 110, 112, 120, and 128 to optimize performance of the system 100. The controller 144 includes a central processing unit (CPU) 138 (which may also be referred to as a processor), a memory 140 containing instructions, and support circuits 142 for the CPU. The controller 144 controls various items directly, or via other computers and/or controllers. In one or more embodiments, the controller 144 is communicatively coupled to dedicated controllers, and the controller 144 functions as a central controller.

The controller 144 is of any form of a general-purpose computer processor that is used in an industrial setting for controlling various substrate processing chambers and equipment, and sub-processors thereon or therein. The memory 140, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 142 of the controller 144 are coupled to the CPU 138 for supporting the CPU 138 (a processor). The support circuits 142 can include cache, power supplies, clock circuits, input/output circuitry and subsystems, and the like. Operational parameters (such as UV light power, inert gas temperature, inert gas pressure, native oxide content, particle concentration, and/or atomic particle concentration) and operations are stored in the memory 140 as software routine(s) that are executed or invoked to turn the controller 144 into a specific purpose controller to control the operations of the various systems/chambers/units/modules described herein. The software routine(s), when executed by the CPU 138, transform the CPU 138 into a specific purpose computer. The software routines may also be stored and/or executed by a second controller (not shown) that is located remotely from the system 100.

The CPU 138 is any electronic circuitry, including, but not limited to one or a combination of microprocessors, microcontrollers, application specific integrated circuits (ASIC), application specific instruction set processor (ASIP), and/or state machines, that communicatively couples to the memory 140 and controls the operation of the system 100. The CPU 138 may be 8-bit, 16-bit, 32-bit, 64-bit or of any other suitable architecture. The CPU 138 may include an arithmetic logic unit (ALU) for performing arithmetic and logic operations, processor registers that supply operands to the ALU and store the results of ALU operations, and a control unit that fetches instructions from memory and executes them by directing the coordinated operations of the ALU, registers and other components. The CPU 138 may include other hardware that operates software to control and process information. The CPU 138 executes software stored on the memory 140 to perform any of the functions described herein. The CPU 138 controls the operation and administration of the system 100 by processing information (e.g., information received from the process chambers 110, 112, 120, and 128, robots 114, and memory 140). The CPU 138 is not limited to a single processing device and may encompass multiple processing devices contained in the same device or computer or distributed across multiple devices or computers. The CPU 138 is considered to perform a set of functions or actions if the multiple processing devices collectively perform the set of functions or actions, even if different processing devices perform different functions or actions in the set.

The memory 140 may store, either permanently or temporarily, data, operational software, or other information for the CPU 138. The memory 140 may include any one or a combination of volatile or non-volatile local or remote devices suitable for storing information. For example, the memory 140 may include random access memory (RAM), read only memory (ROM), magnetic storage devices, optical storage devices, or any other suitable information storage device or a combination of these devices. The software represents any suitable set of instructions, logic, or code embodied in a computer-readable storage medium. For example, the software may be embodied in the memory 140, a disk, a CD, or a flash drive. In particular embodiments, the software may include an application executable by the CPU 138 to perform one or more of the functions described herein. The memory 140 is not limited to a single memory and may encompass multiple memories contained in the same device or computer or distributed across multiple devices or computers. The memory 140 is considered to store a set of data, operational software, or information if the multiple memories collectively store the set of data, operational software, or information, even if different memories store different portions of the data, operational software, or information in the set.

The controller 144 may control the system 100 based off of sensor readings, a system model, and stored readings and calculations. As an example, one or more operating parameters may be measured by one or more sensors positioned along the system 100. The controller 144 may include embedded software and a compensation algorithm to calibrate measurements. The controller 144 may include one or more machine learning algorithms and/or artificial intelligence algorithms that estimate optimized parameters for deposition operation(s), cleaning operations, etching operations, and/or atomic radical treatment operation(s). The one or more machine learning algorithms and/or artificial intelligence algorithms can use, for example, a regression model (such as a linear regression model) or a clustering technique to estimate optimized parameters. The algorithm can be unsupervised or supervised. The one or more machine learning algorithms and/or artificial intelligence algorithms can optimize the operating parameters used in relation to operations described herein.

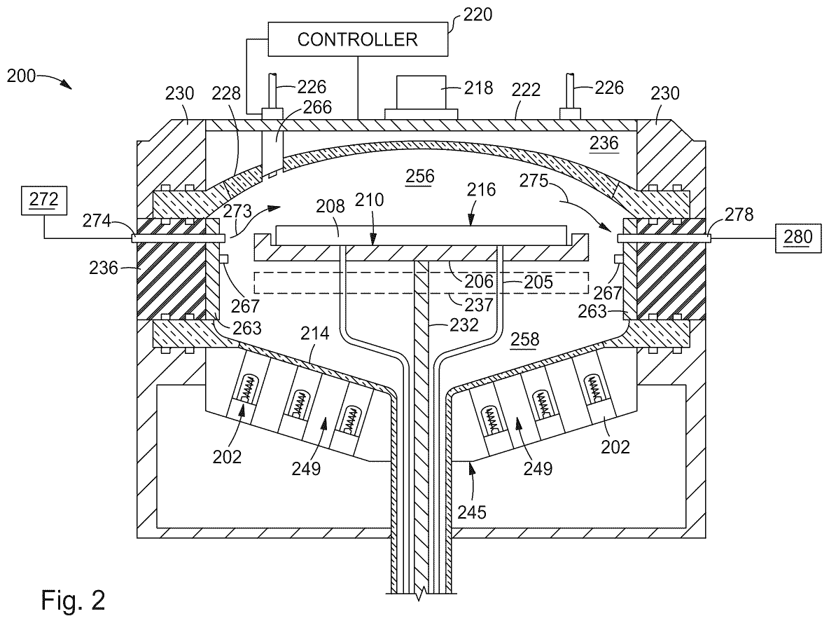

FIG. 2A illustrates a schematic side cross-sectional view of an example process chamber 200 for the semiconductor substrate processing system 100 of FIG. 1, according to certain embodiments of the present disclosure. For example, the process chamber 200 may be the any of the process chambers 110, 112, 120, and/or 128 shown in FIG. 1. The process chamber 200 may a deposition chamber (e.g., an epitaxial deposition chamber). The process chamber 200 may be used to grow an epitaxial film on a substrate 208. The process chamber 200 creates a cross-flow of precursors across a top surface of the substrate 208.

The process chamber 200 may include an array of radiant heating lamps 202 for heating, among other components, a substrate support 206 (e.g., which may be referred to as a susceptor) disposed within the process chamber 200. In some embodiments, the array of radiant heating lamps may be disposed over a window, such as the upper dome 228. The substrate support 206 may be a disk-like substrate support or may be a ring-like substrate support with no central opening, which supports the substrate 208 from the edge of the substrate 208 to facilitate exposure of the substrate 208 to the thermal radiation of the lamps 202.

As shown, a controller 220 and a camera 266 are in communication with the process chamber 200. The controller 220 may be part of and may include the components of the controller 144 shown in FIG. 1. The controller 220 may be used to control processes and methods, such as the operations of the methods described herein. The camera 266 may be used to capture images of the substrate 208 and/or components inside the process chamber 200 for use with processes and methods. The controller 220, camera 266 and the process chamber 200 can be part of a substrate processing system.

The substrate support 206 is located within the process chamber 200 between an upper window (e.g., the upper dome 228) and a lower window (e.g., a lower dome 214). The upper dome 228, the lower dome 214, and a base ring 236 that is disposed between the upper dome 228 and lower dome 214 generally define an internal region of the process chamber 200. The substrate 208 (not to scale) can be brought into the process chamber 200 and positioned onto the substrate support 206 through a loading port. While the upper dome 228 and the lower dome 214 are shown as dome shaped, it is contemplated that planar windows may utilized instead.

The substrate support 206 may be vertically traversed by an actuator (not shown) to a loading position to allow lift pins 205 to contact the lower dome 214, passing through lift pin holes in the substrate support 206 and the central shaft 232. A robot (not shown) may then enter the process chamber 200 to load the substrate 208 onto the lift pins 205. The substrate support 206 then may be actuated up to a processing position, which causes the lift pins 205 to retract through the lift pin holes in the substrate support 206, lowering the substrate 208 onto a top surface 210 of the substrate support 206 with a device side 216 of the substrate 208 facing up. After the substrate 208 is processed in the process chamber 200, the substrate support 206 may be lowered into the loading position to allow lift pins 205 to contact the lower dome 214, passing through the lift pin holes in the substrate support 206 and the central shaft 232, and raise the substrate 208 from the substrate support 206. The robot may then enter the process chamber 200 to engage and remove the substrate 208 from the process chamber 200 though the loading port.

The substrate support 206, while located in the processing position, divides the internal volume of the process chamber 200 into a process gas region 256 that is above the substrate 208 and a purge gas region 258 below the substrate support 206. The substrate support 206 is rotated during processing by the central shaft 232 to minimize the effect of thermal and process gas flow spatial anomalies within the process chamber 200 and thus facilitate uniform processing of the substrate 208. The substrate support 206 is supported by the central shaft 232, which moves the substrate 208 in an up and down direction during loading and unloading, and in some instances, processing of the substrate 208. The substrate support 206 may be formed from silicon carbide or graphite coated with silicon carbide to absorb radiant energy from the lamps 202 and conduct the radiant energy to the substrate 208.

In general, the central window portion of the upper dome 228 and the bottom of the lower dome 214 are formed from an optically transparent material such as quartz. “Optically transparent” here means generally transmissive to radiation, but not necessarily 200% transmissive. As will be discussed in more detail below with respect to FIG. 2, the thickness and the degree of curvature of the upper dome 228 may be configured in accordance with the present disclosure to provide a flatter geometry for uniform flow uniformity in the process chamber.

One or more lamps, such as an array of lamps 202, can be disposed adjacent to and beneath the lower dome 214 in a specified manner around the central shaft 232 to independently control the temperature at various regions of the substrate 208 as the process gas passes over, thereby facilitating the deposition of a material onto the upper surface of the substrate 208. While not discussed here in detail, the deposited material may include gallium arsenide, gallium nitride, or aluminum gallium nitride, among other materials.

The lamps 202 include bulbs that heat the substrate 208 to a temperature within a range of about 200 degrees Celsius to about 2600 degrees Celsius. Each lamp 202 is coupled to a power distribution board (not shown) through which power is supplied to each lamp 202. The lamps 202 are positioned within a lamphead 245 which may be cooled during or after processing by, for example, a cooling fluid introduced into channels 249 located between the lamps 202. The lamphead 245 conductively and radiatively cools the lower dome 214 due in part to the close proximity of the lamphead 245 to the lower dome 214. The lamphead 245 may also cool the lamp walls and walls of the reflectors (not shown) around the lamps. Alternatively, the lower dome 214 may be cooled by a convective approach. Depending upon the application, the lampheads 245 may or may not be in contact with the lower dome 214.

A circular shield 267 may be optionally disposed around the substrate support 206 and surrounded by a liner assembly 263. The shield 267 prevents or minimizes leakage of heat/light noise from the lamps 202 to the device side 216 of the substrate 208 while providing a pre-heat zone for the process gases. The shield 267 may be made from chemical vapor deposition silicon carbide (CVD SiC), sintered graphite coated with SiC, grown SiC, opaque quartz, coated quartz, or any similar, suitable material that is resistant to chemical breakdown by process and purging gases.

The liner assembly 263 is sized to be nested within or surrounded by an inner circumference of the base ring 236. The liner assembly 263 shields the processing volume (e.g., the process gas region 256 and purge gas region 258) from metallic walls of the process chamber 200. The metallic walls may react with precursors and cause contamination in the processing volume. While the liner assembly 263 is shown as a single body, the liner assembly 263 may include one or more liners with different configurations.

An optical pyrometer 218 is positioned on the process chamber 200. The pyrometer 218 may sense or measure the temperature within the process chamber 200 (e.g., the temperature of the substrate support 206). The measurements from the pyrometer 218 may be used to adjust or control the temperature in the process chamber 200. This optical pyrometer 218 may also measure the temperature of the device side 216 of the substrate 208 (e.g., having an unknown emissivity because heating the substrate top surface 216 in this manner is emissivity independent). As a result, the optical pyrometer 218 may sense radiation from the hot substrate 208 that conducts from the substrate support 206, with minimal background radiation from the lamps 202 directly reaching the optical pyrometer 218.

A reflector 222 may be optionally placed outside the upper dome 228 to reflect infrared light that is radiating off the substrate 208 back onto the substrate 208. The reflector 222 may be secured to the upper dome 228 using a clamp ring 230. The reflector 222 can be made of a metal such as aluminum or stainless steel. The efficiency of the reflection can be improved by coating a reflector area with a highly reflective coating such as gold. The reflector 222 can have one or more conduits 226 connected to a cooling source (not shown). The conduit 226 connects to a passage (not shown) formed on a side of the reflector 222. The passage may carry a flow of a fluid such as water and may run horizontally along the side of the reflector 222 in any desired pattern covering a portion or entire surface of the reflector 222 for cooling the reflector 222.

A process gas supply source 272 introduces a process gas into the process gas region 256 through a process gas inlet 274 formed in the sidewall of the base ring 236. The process gas inlet 274 directs the process gas in a generally radially inward direction. During the film formation process, the substrate support 206 may be located in the processing position, which is adjacent to and at about the same elevation as the process gas inlet 274, allowing the process gas to flow up and round along flow path 273 across the upper surface of the substrate 208 in a laminar flow fashion. The process gas exits the process gas region 256 (along flow path 275) through a gas outlet 278 located on the side of the process chamber 200 opposite the process gas inlet 274. Removal of the process gas through the gas outlet 278 may be facilitated by a vacuum pump 280 coupled thereto. As the process gas inlet 274 and the gas outlet 278 are aligned to each other and disposed approximately at the same elevation, such a parallel arrangement, when combing with a flatter upper dome 228 (as will be discussed in detail below), may provide a generally planar, uniform gas flow across the substrate 208. Further radial uniformity may be provided by the rotation of the substrate 208 by the substrate support 206.

The substrate 208 may be transferred into and out of the internal volume of the process chamber 200 through a transfer door 237 (such as a slit valve). When the transfer door 237 is open, a transfer robot (with a substrate disposed thereon) can extend into the internal volume through the transfer door 237 such that the lift pins 205 can lift the substrate 208 from the transfer robot and land the substrate 208 on the substrate support 206 for processing. After processing, the lift pins 205 can lift the substrate from the substrate support 206 and land the substrate back on the transfer robot, and the transfer robot can be retracted through the open transfer door 237 to remove the substrate from the process chamber 200.

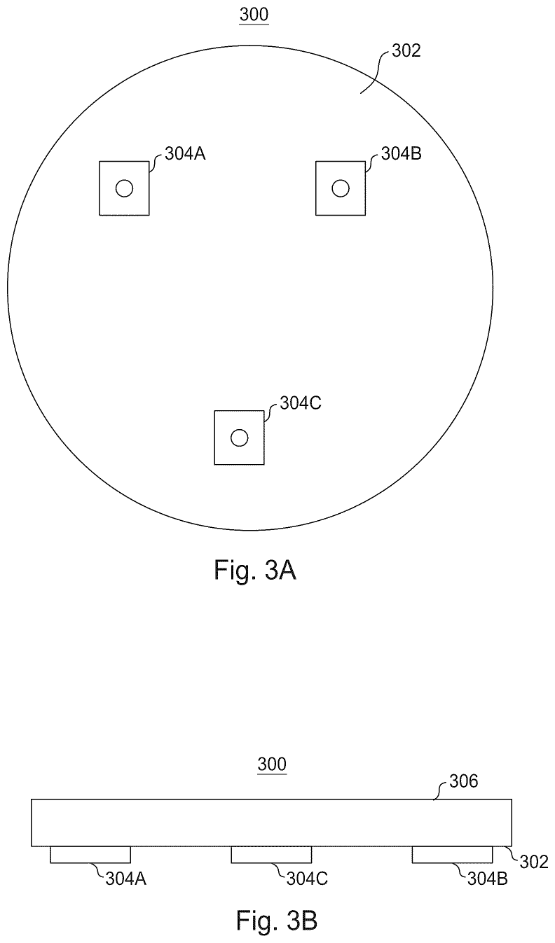

FIG. 3A shows a surface 302 of the semiconductor substrate 300. The surface 302 may be a bottom surface of the substrate 300 that faces the susceptor when the semiconductor substrate 300 is positioned on the susceptor. Multiple cameras 304 are positioned on the surface 302 of the substrate 300. In the example of FIG. 3A, the cameras 304A, 304B, and 304C are positioned on the surface 302. The cameras 304 may face away from the substrate 300 such that the cameras 304A, 304B, and 304C are directed towards the susceptor when the substrate 300 is positioned on the susceptor.

The cameras 304A, 304B, and 304C may be positioned on the surface 302 such that the cameras 304A, 304B, and 304C align with different lift pin holes on the susceptor. Lift pins may extend through the lift pin holes to hold the substrate 300 when the substrate 300 is being loaded onto the susceptor. If the substrate 300 is not aligned with the susceptor during loading, then the cameras 304A, 304B, and 304C may not align with the lift pin holes on the susceptor.

The cameras 304A, 304B, and 304C may have any orientation on the surface 302 of the substrate 300. In the example of FIG. 3A, the cameras 304A, 304B, and 304C have the same orientation on the surface 302. In some embodiments, the cameras 304A, 304B, and 304C have different orientations. For example, the cameras 304A, 304B, and 304C may be oriented radially (e.g., along radii of the substrate 300).

FIG. 3B shows a side view of the semiconductor substrate 300. As seen in FIG. 3B, the substrate 300 includes the surface 302 and a surface 306 opposite the surface 302. For example, the surface 302 may be a bottom surface of the substrate 300, and the surface 306 may be a top surface of the substrate 300. The surface 302 may face the susceptor when the substrate 300 is being positioned on the susceptor, and the surface 306 may face away from the susceptor. The cameras 304A, 304B, and 304C are positioned on the surface 302 and are also directed towards the susceptor when the substrate 300 is being positioned on the susceptor.

In some embodiments, lights (e.g., light emitting diodes) are also positioned on the surface 302. For example, the lights may be formed as rings around each of the cameras 304 on the surface 302. The lights may be operated to emit a light towards the susceptor when the substrate 300 is being loaded onto the susceptor. In this manner, the lights illuminate the susceptor and/or the lift pin holes, which allows the cameras 304 to capture images of the susceptor and/or lift pin holes. The lights may emit light of any color (e.g., red, blue, white, etc.).

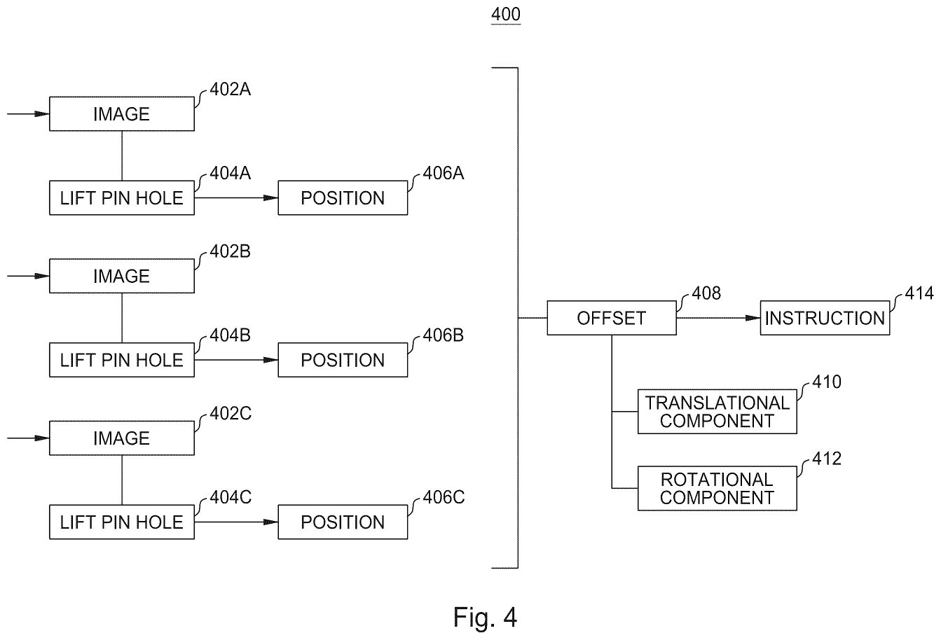

FIG. 4 illustrates an example operation 400 performed by the semiconductor substrate processing system 100 of FIG. 1, according to certain embodiments of the present disclosure. Generally, a controller (e.g., the controller 144 shown in FIG. 1) performs the operation 400. By performing the operation 400, the controller determines an offset between a substrate (e.g., the substrate 300 shown in FIGS. 3A and 3B) and a susceptor and moves the substrate to correct the offset.

The controller begins by receiving images 402 captured by the cameras (e.g., the cameras 304 shown in FIGS. 3A and 3B) positioned on the substrate. As discussed previously, the cameras may be directed towards the susceptors and lift pin holes when the substrate is being loaded into a process chamber. As a result, the images 402 may show lift pin holes 404 (which may be the lift pin holes for the lift pins 205 shown in FIG. 2). In the example of FIG. 4, the controller receives the images 402A, 402B, and 402C. These images 402A, 402B, and 402C may be captured by different cameras (e.g., the cameras 304A, 304B, and 304C shown in FIGS. 3A and 3B) positioned on the substrate and may show different lift pin holes. The image 402A shows a lift pin hole 404A. The image 402B shows a lift pin hole 404B. The image 402C shows a lift pin hole 404C.

In some embodiments, the controller may move a robot holding the substrate to maintain a minimum distance between the substrate and the susceptor and/or lift pin holes when the cameras are capturing the images 402. This distance may be governed by the features of the cameras (e.g., the focus, field of view, etc. of the cameras). In some instances, the controller may also move the susceptor closer or farther away from the camera to adjust the distance between the substrate and the susceptor. In this manner, the controller may ensure that the lift pin holes are captured in the images 402 and that the lift pin holes are in focus.

The controller analyzes the images 402 to detect positions 406 of the lift pin holes 404 shown in the images 402. For example, the controller may determine coordinates that indicate where the lift pin holes 404 appear in the images 402. The coordinates may indicate the pixels in the images 402 that the lift pin holes 404 occupy. In the example of FIG. 4, the lit pin hole 404A has a position 406A in the image 402A, the lift pin hole 404B has a position 406B in the image 402B, and the lift pin hole 404C has a position 406C in the image 402C. Because the cameras used to capture the images 402 are positioned on the substrate such that the cameras align with the lift pin holes if the substrate is properly positioned during loading into the process chamber, the lift pin holes 404 may appear in the center of the images 402 if the substrate is properly positioned. Any offset in the pixels occupied by the lift pin holes 404 in the images 402 (e.g., offsets from center of the images 402) may indicate that the substrate is not properly positioned.

The controller analyzes the positions 406 of the lift pin holes 404 in the images 402 to determine an offset 408 of the substrate. As discussed above, if the lift pin holes 404 appear in the center of the images 402, then the offset 408 may be zero, indicating that the substrate is properly positioned. If the substrate is not properly positioned, then the offset 408 is larger than zero. The controller may determine from the positions 406 how far off-center the lift pin holes 404 are in the images 402. From these positions 406, the controller determines the offset 408. For example, the controller may determine from the positions 406 a distance and a direction by which the substrate is misaligned during loading. The offset 408 may indicate this distance and direction.

In some embodiments, the controller may determine a translational component 410 and a rotational component 412 of the offset 408. The translational component 410 may indicate a distance and a direction in the plane of the substrate. The rotational component 412 may indicate an angular rotation in the plane of the substrate. The controller may correct for the translational component 410 by moving the substrate (e.g., by moving the robot holding the substrate). In some instances, however, the controller may not correct for the rotational component 412. For example, if the substrate is a circular disk, then angular rotation in the plane of the substrate may not cause the substrate to become misaligned with the susceptor during loading. As a result, the controller may not correct for the rotational component 412 of the offset 408. Generally, the translational component 410 and the rotational component 412 refer to the positioning of the wafer relative to the susceptor, rather than the positioning of the robot holding the substrate. The controller may still adjust the translational and rotational position of the robot to move and place the substrate.

The controller moves a robot (e.g., the factory interface robot 114 shown in FIG. 1) holding the substrate to adjust for the offset 408. The controller generates an instruction 414 that indicates how the robot should move and communicates the instruction 414 to the robot to move the robot. The instruction 414 may indicate a direction and distance that the robot should move the substrate to reduce or compensate for the offset 408. The robot may then move the substrate by the indicated distance and direction to bring the substrate more in alignment with the susceptor before loading the substrate onto the susceptor.

In some embodiments, moving the robot may have reduced the offset 408, but the substrate may still not be considered aligned with the lift pin holes 404. The controller may make additional adjustments or movements to further reduce the offset 408. For example, the controller may receive additional images 402 from the cameras on the substrate after moving the robot. The controller analyzes these images 402 to determine whether the lift pin holes 404 in the images 402 are centered in the images. If the lift pin holes 404 are not centered, then the controller may determine the offset 408 and further move the robot to further reduce or compensate for the offset 408. The controller may continue this process of moving the substrate and determining the offset 408 until the substrate has been brought into alignment with the susceptor and/or lift pin holes. In some instances, the controller may compare the offset 408 with a threshold to determine whether the substrate is aligned with the susceptor and/or lift pin holes. If the offset 408 falls below the threshold, then the controller may determine that the substrate is properly aligned with the susceptor and/or lift pin holes and load the substrate onto the lift pin holes and/or lift pins.

In certain embodiments, the controller stores the position of the robot when the controller determines that the substrate is aligned with the lift pin holes 404. The controller may then move the robot into the stored position for subsequent substrates instead of repeating the process of aligning the substrates with the lift pin holes. In this manner, the computer system uses the operation 400 to effectively calibrate the robot, and the controller may use the calibration for subsequent substrates.

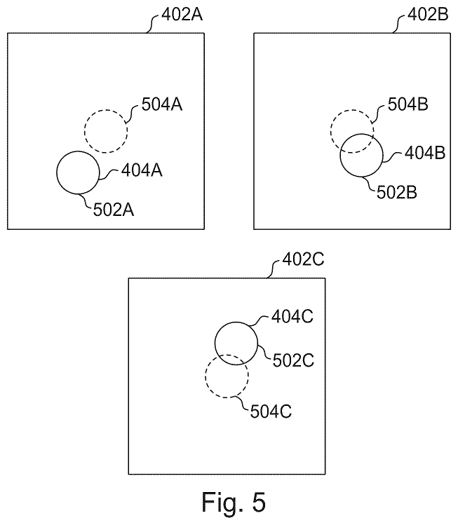

FIG. 5 illustrates example images 402 in the semiconductor substrate processing system 100 of FIG. 1, according to certain embodiments of the present disclosure. As seen in FIG. 5, the images 402A, 402B, and 402C show different lift pin holes 404A, 404B, and 404C, respectively. The lift pin holes 404A, 404B, and 404C appear at different positions 502A, 502B, and 502C in the images 402A, 402B, and 402C. Additionally, the centers 504A, 504B, and 504C of each image 402A, 402B, and 402C are indicated using a dashed circle. The controller may analyze the images 402A, 402B, and 402C to determine how far the lift pin holes 404A, 404B, and 404C are from the centers 504A, 504B, and 504C of the images 402A, 402B, and 402C, which the controller uses to determine the offset.

When the controller moves the robot to reduce or compensate for the offset, the lift pin holes 404 may be moved closer to the centers 504 in subsequent images 402. When the lift pin holes 404 are positioned at the centers 504 (or within a threshold of the centers 504), the controller considers the substrate properly positioned and loads the substrate onto the lift pin holes and/or lift pins.

In this manner, the controller aligns the substrate with the susceptor before loading the substrate. As a result, the controller reduces misalignment between the substrate and the susceptor, which improves the uniformity of process results on the substrate, reduces temperature gradients in the process chamber, and reduces arcing in the process chamber.

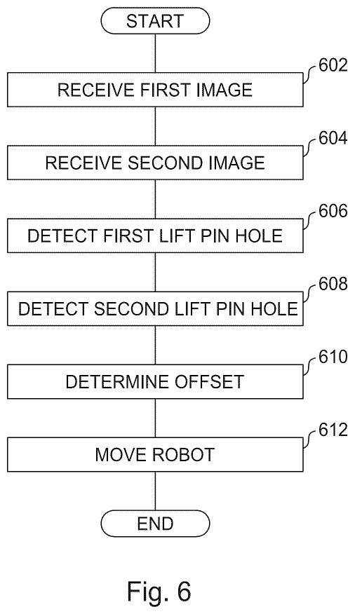

FIG. 6 is a flowchart of an example method 600 performed by the semiconductor substrate processing system 100 of FIG. 1, according to certain embodiments of the present disclosure. In certain embodiments, a controller (e.g., the controller 144 shown in FIG. 1) performs the method 600. By performing the method 600, the controller brings a substrate into closer alignment with a center of a susceptor before loading the substrate onto lift pins.

In block 602, the controller receives a first image. The first image may be captured by a first camera positioned on the substrate. The first camera may be directed towards the susceptor and/or lift pin holes. The first camera may also be positioned such that the first camera aligns with a lift pin hole if the substrate is properly aligned with the susceptor. In block 604, the controller receives a second image. The second image may be captured by a second camera positioned on the substrate. The second camera may also be directed towards the susceptor and/or lift pin holes. The second camera may be positioned such that the second camera aligns with another lift pin hole if the substrate is properly aligned with the susceptor. In this manner, the first camera and the second camera capture different images of different lift pin holes.

In block 606, the controller detects a first lift pin hole in the first image. The controller may analyze the first image to determine a position of the first lift pin hole in the first image. For example, the controller may determine how far from the center of the first image does the first lift pin hole appear in the first image. In block 608, the controller detects a second lift pin hole in the second image. The controller analyzes the second image to determine a position of the second lift pin hole in the second image. For example, the controller may determine how far from the center of the second image does the second lift pin hole appear in the second image.

In block 610, the controller determines an offset. The offset may indicate how misaligned the substrate is with the susceptor. For example, the offset may indicate a distance and/or a direction of the misalignment. In some embodiments, the controller determines from the positions of the first lift pin hole and the second lift pin hole in the first and second images that the substrate has a translational offset with the susceptor (e.g., offset in the plane of the substrate). The controller may determine the distance and/or direction of this translational offset. The controller may then base the offset on this distance and/or direction.

In block 612, the controller moves a robot holding the substrate to reduce or compensate for the offset. For example, the controller may move the robot the distance indicated by the offset in a direction opposite the direction indicated by the offset, which correspondingly moves the substrate held by the robot. The controller may generate and communicate instructions to the robot to move the robot in this manner.

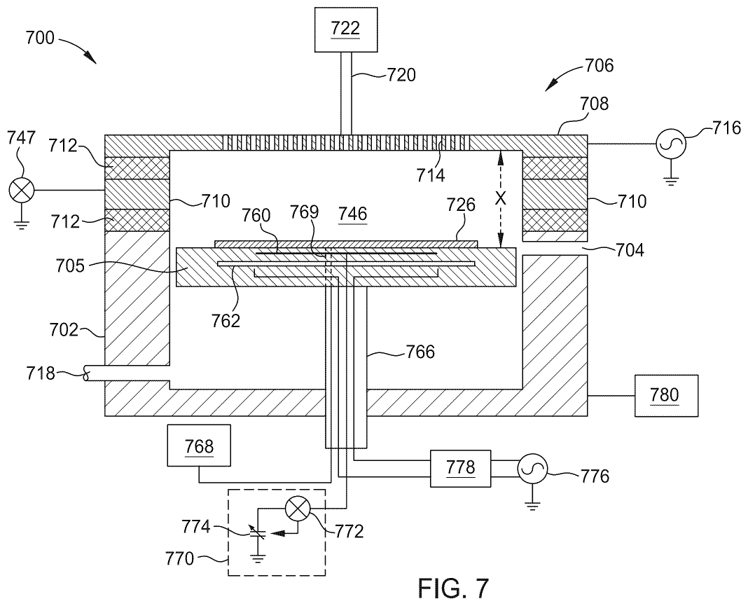

FIG. 7 is a schematic cross sectional view of an example process chamber 700 configured according to various embodiments of the present disclosure. The process chamber 700 may be part of a plasma enhanced chemical vapor deposition (PECVD) system, but any other process chamber may fall within the scope of the embodiments, including other plasma deposition chambers. By utilizing, in particular, a PECVD system, the cycle time of the deposition processes is reduced, resulting in higher throughput. The process chamber 700 includes a chamber body 702, a lid assembly 706, and a substrate support 705. The lid assembly 706 is disposed at an upper end of and is supported by the chamber body 702, and the substrate support 705 is at least partially disposed within the chamber body 702. The chamber body 702, lid assembly 706, and substrate support 705 together define a processing volume 746 within the process chamber 700 in which a substrate 726 may be processed. The processing volume 746 may be accessed through a port 704 formed in the chamber body 702 that facilitates transfer of a substrate into and out of the processing volume 746 of the process chamber 700.

The lid assembly 706 includes a gas distributor 708, a modulation electrode 710, and insulators 712. In some embodiments, the modulation electrode 710 is optional. The insulator 712, which may be a dielectric material such as a ceramic or metal oxide, for example aluminum oxide and/or aluminum nitride. The insulator 712 contacts the modulation electrode 710 and separates the modulation electrode 710 electrically and thermally from the gas distributor 708 and from the chamber body 702. The gas distributor 708 (e.g., showerhead) has passages 714 therethrough for admitting process gas into the processing volume 746. A pair of insulators (e.g., annular insulators) are disposed between the gas distributor 708 and the modulation electrode 710. The modulation electrode 710 is annular and circumscribes the processing volume 746. The modulation electrode 710 is optional, and may be omitted.

Process gases (e.g., one or more precursor and one or more inert carrier gas) may be provided through the conduit 720 from a gas source 722 to be introduced into the process chamber 700. The processing gas from the conduit 720 enters the processing volume 746 through the passages 714 in the gas distributor 708 such that the processing gas is uniformly distributed in the processing volume 746. In one embodiment, the passages 714 in the gas distributor 708 may be radially distributed and gas flow to each of the passages 714 may be separately controlled to further facilitate gas uniformity within the processing volume 746.

The processing gases can be evacuated from the processing volume 746 through an outlet 718 which may be located at any convenient location along the chamber body 702. In some embodiments, the outlet 718 may be associated with a vacuum pump (not shown) fluidly coupled to the processing volume 746. The vacuum pump may be part of a gas and pressure control system of the processing chamber 700. The gas and pressure control system maintains the process volume at a pressure of about 3 Torr to about 50 Torr.

In some embodiments, which may be combined with other embodiments, portions of the gas distributor 708 may be heated using a resistive heater (not shown) or thermal fluid disposed in a conduit (not shown) through a portion of the gas distributor 708 or otherwise in direct contact or thermal contact with the gas distributor 708. The conduit may be disposed through an edge portion of the gas distributor 708 to avoid disturbing the gas flow function of the gas distributor 708. Heating the edge portion of the gas distributor 708 may be useful to reduce the tendency of the edge portion of the gas distributor 708 to be a heatsink within the process chamber 700.

In some embodiments, which may be combined with other embodiments, the walls of the chamber body 702 may also be heated to similar effect. Heating the chamber surfaces exposed to the plasma also minimizes deposition, condensation, and/or reverse sublimation on the chamber surfaces, reducing the cleaning frequency of the chamber and increasing mean cycles per clean. Higher temperature surfaces also promote dense deposition that is less likely to produce particles that fall onto a substrate. Thermal control conduits with resistive heaters and/or thermal fluids (not shown) may be disposed through the chamber walls to achieve thermal control of the chamber walls. Temperature of all surfaces may be controlled by a controller.

The gas distributor 708 is coupled to a RF power source 716, such as a RF generator, as shown in FIG. 7. In other embodiments, the gas distributor 708 may be coupled to ground. The RF power source 716 is electrically connected to the gas distributor 708 and is configured to apply a RF potential to the gas distributor 708 to facilitate the generation of plasma in the interior processing volume 746.

The RF power source 716 may be a high frequency RF power source (“HFRF power source”) capable of generating an HFRF power (e.g., at a frequency of about 10 MHz to about 40 MHz, e.g., about 20 MHz to about 22 MHz, about 22 MHz to about 24 MHz, about 24 MHz to about 26 MHz, about 26 MHz to about 28 MHz, or about 28 MHz to about 30 MHz). The HFRF power source can be designed for use with a fixed match or automatch and can regulate the power delivered to the load, eliminating concerns about forward and reflected power. The automatch may cover multiple impedance ranges. In other embodiments, the RF power source 716 may be a low frequency RF power source (“LFRF power source”) capable of generating an LFRF power (e.g., at a frequency of about 350 kHz to about 2 MHz). The process chamber 700 includes a HFRF power source and a LFRF power source to enable pulsing of RF and LF power simultaneously.

Without being bound by theory, increasing a HFRF power source can provide an increase in the radical production rate (e.g., C₂H production rate and H production rate, when using acetylene as a precursor) and neutral production rate, thereby producing a more conformal and/or uniform carbon gapfill in trenches between one or more features, and reducing pattern loading effects.

Without being bound by theory, the LFRF power may increase the ion energy distribution function (IEDF) and decreases the ion angular distribution function (IADF), enabling increased ion flux during the generation of the plasma in the interior processing volume 746 and enabling increased ion directionality. At lower frequencies, ions experience a more constant electric field over each cycle, enabling the ions to gain more energy and uniformity and resulting in a narrower IEDF. At higher frequencies, the electric field oscillates rapidly, causing ions to experience a varying field as they traverse the sheath. This results in a broader IEDF and leads to a wider range of energies and complex energy transfer dynamics. This enables lower energy peaks, favoring a radical driven process.

At lower frequencies, ions have more time to respond to the electric field direction, resulting in a more collimated angular distribution. The ions are more likely to travel straight towards the electrode, leading to a narrow IADF. At higher frequencies, the ions experience changes in direction due to the rapidly changing electric field, which may cause ions to be deflected or scattered, broadening the IADF and reducing the directionality of the ion beam. Narrower IADF helps with directional fill/etch, while a broader IADF helps with conformal fill. Therefore, a combination of HFRF and LFRF enables an increase in the ion production and the ion directionality. Without being bound by theory, an ion driven regime (e.g., IEDF) reduces a deposition rate and decreases sheath potential. The sheath potential is the voltage difference between the plasma generated in the process chamber 700 and the substrate 726. Decreasing the sheath potential in an ion driven regime, thus, decreases the deposition rate. At higher frequencies (e.g., HFRF), the sheath responds quickly to an oscillating electric field. The rapid oscillations restricts ion movement. This rapid response typically results in a thinner sheath, as ions do not have sufficient time to penetrate deeply into the sheath before the electric field reverses direction. At lower frequencies (e.g., LFRF), the sheath has more time to respond to the oscillating field, allowing ions to further penetrate and resulting in a thicker sheath. The slower oscillation allows ions to move deeper into the sheath. The sheath thickness increases as ions travel further into the sheath, causing it to expand, as the spatial distribution of positive ions require a larger region to maintain charge balance and accommodate the electric field.

Meanwhile, a radical driven regime (e.g., IADF) increases the deposition rate, as neutral/radical regimes are driven with thermal flux, which is larger than a diffusive flux that drives the ion regime. The diffusive flux, however, enables increased uniformity in gapfill deposition between narrower critical dimension structures and wider critical dimension structures.

By pulsing HFRF and LFRF, the IEDF and IADF are tunable to improve deposition uniformity, reduce the thermal load, increase the ability for thermal management, minimize the charging effects, and enhance the plasma chemistry. A low pulsing frequency enables a broader IEDF and IADF is enabled due to longer off periods, thus enabling more ion energy loss and directional scattering. A high pulsing frequency leads to narrower IEDF and IADF due to shorter off periods, thus maintaining more consistent acceleration and directionality. Pulsing HFRF/LFRF, e.g., from 200 Hz to 10,000 Hz, enables precise control of the duration of the ion/electron behavior. Adjusting pulsing frequency and duty cycle provides a means to control the IEDF and IADF in micro to milli-level timescales, enabling the tuning of the plasma process in various applications and for gap filling different CDs. By changing the pulsing frequency, duty cycle, and RF frequency, IADF and IEDF can be modulated in short timescales to deposit or etch the CDs and control the lifetime of ions and radicals for the process. Thus, pulsing and duty cycle can be used to modulate between the IADF and IEDF regions in a controlled manner, and to toggle between anisotropic deposition (higher ion regime) and isotropic deposition (higher radical regime) and mimic different pressure regimes.

Pulsing reduces the average power delivered to the substrate 726, minimizing thermal damage to the substrate 726. Pulsing also allows the substrate 726 and surrounding equipment to cool down, preventing overheating. Pulsing enables charge to dissipate during off periods, reducing the risk of surface charging and related defects such as arcing. Further still, the ratio of ion/neutral density enables increased control over the chemical reactions. Using continuous wave (CW) pulsing enables similar phenomena to the pulsing HFRF/LFRF.

Controlling the IADF and IEDF via RF frequency, pulsing, and duty cycle enables the imitation of different pressure regimes. For example, at low pressures, the IEDF has a narrower distribution, and higher and more consistent ion energies due to fewer collisions. Meanwhile, the IADF has a narrower angular distribution, more collimated ion trajectories, and more perpendicular ion strikes on the substrate 726. These condition can be replicated using LFRF with higher pulsing frequency and duty cycle. The duty cycle may be from about 10% to about 90%, such as about 25% to about 75%, such as about 40% to about 60%.

In another example, at high pressure, the IEDF has a broader distribution and wider range of ion energies due to frequent collisions. Meanwhile, the IADF has a broader angular distribution and more scattered ion trajectory. These conditions can be replicated using HFRF at a higher pulsing frequency and duty cycle. The duty cycle may be from about 70% to about 90% %, such as about 25% to about 75%, such as about 40% to about 60%. In further embodiments, which can be combined with other embodiments, an additional power source 747 may be added with the RF power source 716 to provide a dual RF power source to the process chamber 700. It is contemplated the modulation electrode 710 and the additional power source 747 may be omitted.

The substrate support 705 may be disposed within the process chamber 700. The substrate support 705 may support the substrate 726 during processing. A first electrode 760 and a second electrode 762 are disposed in and/or on the substrate support 705. Further, in some embodiments, a heater element (not shown) may be embedded in the substrate support 705. The heater element can be operable to controllably heat the substrate support 705 and the substrate 726 positioned thereon to a target temperature, such as to maintain the substrate 726 at a temperature in a range from about 350 degrees Celsius to about 500 degrees Celsius. The substrate support 705 is a distance X from the gas distributor. The distance X is about 250 mils to about 750 mils, such as about 500 mils.

The substrate support 705 is coupled to a shaft 766 for support. The shaft 766 can provide a conduit from a gas source 768 and electrical and temperature monitoring leads (not shown) between the substrate support 705 and other components of the process chamber 700. In some examples, a purge gas may be provided from the gas source 768 to the backside of the substrate 726 through one or more purge gas inlets 769 connected to the substrate support 705. The purge gas flowed toward the backside of the substrate 726 can help prevent particle contamination caused by deposition on the backside of the substrate 726. The purge gas may also be used as a form of temperature control to cool the backside of the substrate 726. Although not illustrated, the shaft 766 may be coupled to an actuator (not shown) which extends through a centrally-located opening formed in a bottom of the chamber body 702. The actuator may be flexibly sealed to the chamber body 702 by bellows (not shown) that prevent vacuum leakage from around the shaft 766. The actuator can allow the substrate support 705 to be moved vertically within the chamber body 702 between a process position and a lower, transfer position. The transfer position is slightly below the port 704 in the chamber body 702. In operation, the substrate support 705 may be elevated to a position in close proximity to the lid assembly 706 for processing.

The first electrode 760 may be embedded within the substrate support 705 or coupled to a surface of the substrate support 705. The first electrode 760 may be a plate, a perforated plate, a mesh, a wire screen, or any other distributed arrangement. The first electrode 760 may be a tuning electrode and may be coupled to a tuning circuit 770. The tuning circuit 770 may have an electronic sensor 772 and an electronic controller, such as a variable capacitor 774 electrically connected between the first electrode 760 and an electrical ground. The electronic sensor 772 may be a voltage or current sensor and may be coupled to the variable capacitor 774 to provide further control over plasma conditions in the processing volume 746.

The second electrode 762, which may be a bias electrode and/or an electrostatic chucking electrode, may be coupled to the substrate support 705. The second electrode 762 may be coupled to a bias power source 776 through an impedance matching circuit 778. The bias power source 776 may be DC power, pulsed DC power, RF power, pulsed RF power, or a combination thereof (e.g., pulsing HFRF or continuous wave HFRF).

In operation, the substrate 726 is disposed on the substrate support 705, and process gases are flowed through the lid assembly 706 according to any desired flow plan. Electric power is coupled to the gas distributor to establish a plasma in the processing volume 746. The substrate 726 may be subjected to an electrical bias using the bias power source 776, if desired.

A controller 780 is coupled to the process chamber 700. The controller 780 controls various processing parameters of the process chamber 700, such as the gas flow rate, the temperature of the substrate 726, the position of the substrate 726, and other parameters. The controller 780 controls the various processing parameters by controlling various components of the process chamber 700, such as the RF power source 716, the additional power source 747, the tuning circuits 744 and 770, the shaft 766, the gas source 722, and other components.

Embodiments of the disclosure have been described above with reference to specific embodiments and numerous specific details are set forth to provide a more thorough understanding of the disclosure. Persons skilled in the art, however, will understand that various modifications and changes may be made thereto without departing from the broader spirit and scope of the disclosure. The foregoing description and drawings are, accordingly, to be regarded in an illustrative rather than a restrictive sense.

While the foregoing is directed to embodiments of the present disclosure, other and further embodiments of the disclosure may be devised without departing from the basic scope thereof, and the scope thereof is determined by the claims that follow.

What is claimed is:

1. A controller for moving a semiconductor substrate, the controller comprising:
one or more memories; and
one or more processors communicatively coupled to the one or more memories, a combination of the one or more processors configured to:
receive a first image from a first camera positioned on the semiconductor substrate and a second image from a second camera positioned on the semiconductor substrate, wherein the first camera is different from the second camera;
detect a first lift pin hole in the first image and a second lift pin hole in the second image;
determine, based on a position of the first lift pin hole in the first image and a position of the second lift pin hole in the second image, an offset for the semiconductor substrate; and
move a robot holding the semiconductor substrate based on the offset.

2. The controller of claim 1, wherein the combination of the one or more processors is further configured to receive a third image from a third camera positioned on the semiconductor substrate, wherein the third camera is different from the first camera and the second camera, and wherein the offset is determined further based on the third image.

3. The controller of claim 1, wherein moving the robot reduces the offset.

4. The controller of claim 1, wherein the combination of the one or more processors is further configured to move the robot to place the semiconductor substrate onto the first lift pin hole and the second lift pin hole after moving the robot based on the offset.

5. The controller of claim 1, wherein the offset comprises a rotational component and a translational component and wherein moving the robot is based on the translational component rather than the rotational component.

6. The controller of claim 1, wherein the combination of the one or more processors is further configured to move the robot to maintain at least a minimum distance between the semiconductor substrate and the first lift pin hole while the first camera captures the first image.

7. The controller of claim 1, wherein moving the robot aligns the first camera with the first lift pin hole and the second camera with the second lift pin hole.

8. A method for moving a semiconductor substrate comprising:
receiving a first image from a first camera positioned on a semiconductor substrate and a second image from a second camera positioned on the semiconductor substrate, wherein the first camera is different from the second camera;
detecting a first lift pin hole in the first image and a second lift pin hole in the second image;
determining, based on a position of the first lift pin hole in the first image and a position of the second lift pin hole in the second image, an offset for the semiconductor substrate; and
moving a robot holding the semiconductor substrate based on the offset.

9. The method of claim 8, further comprising receiving a third image from a third camera positioned on the semiconductor substrate, wherein the third camera is different from the first camera and the second camera, and wherein the offset is determined further based on the third image.

10. The method of claim 8, wherein moving the robot reduces the offset.

11. The method of claim 8, further comprising moving the robot to place the semiconductor substrate onto the first lift pin hole and the second lift pin hole after moving the robot based on the offset.

12. The method of claim 8, wherein the offset comprises a rotational component and a translational component and wherein moving the robot is based on the translational component rather than the rotational component.

13. The method of claim 8, further comprising moving the robot to maintain at least a minimum distance between the semiconductor substrate and the first lift pin hole while the first camera captures the first image.

14. The method of claim 8, wherein moving the robot aligns the first camera with the first lift pin hole and the second camera with the second lift pin hole.

15. A non-transitory computer readable medium storing instructions for moving a semiconductor substrate, wherein when the instructions are executed by a combination of one or more processors, the instructions cause the combination of the one or more processors to:
receive a first image from a first camera positioned on the semiconductor substrate and a second image from a second camera positioned on the semiconductor substrate, wherein the first camera is different from the second camera;
detect a first lift pin hole in the first image and a second lift pin hole in the second image;
determine, based on a position of the first lift pin hole in the first image and a position of the second lift pin hole in the second image, an offset for the semiconductor substrate; and
move a robot holding the semiconductor substrate based on the offset.

16. The medium of claim 15, wherein the instructions further cause the combination of the one or more processors to receive a third image from a third camera positioned on the semiconductor substrate, wherein the third camera is different from the first camera and the second camera, and wherein the offset is determined further based on the third image.

17. The medium of claim 15, wherein moving the robot reduces the offset.

18. The medium of claim 15, wherein the instructions further cause the combination of the one or more processors to move the robot to place the semiconductor substrate onto the first lift pin hole and the second lift pin hole after moving the robot based on the offset.

19. The medium of claim 15, wherein the offset comprises a rotational component and a translational component and wherein moving the robot is based on the translational component rather than the rotational component.

20. The medium of claim 15, wherein the instructions further cause the combination of the one or more processors to move the robot to maintain at least a minimum distance between the semiconductor substrate and the first lift pin hole while the first camera captures the first image.
